(19) United States
(12) Patent Application Publication
(10) Pub. No.: US 2011/0228481 A1
(43) Pub. Date: Sep. 22, 2011

(54) THERMALLY CONDUCTIVE INTERFACE MEANS

(75) Inventor: Jeff BIAR, Taipei County (TW)

(73) Assignee: DOMINTECH CO., LTD., Wugu Township (TW)

(21) Appl. No.: 12/727,870

(22) Filed: Mar. 19, 2010

(51) Int. Cl. H05K 7/20; F28F 7/00

(52) U.S. Cl. 361/705; 165/185

(57) ABSTRACT

A highly thermally conductive interface means comprises a plurality of non-particulate solid components and a liquid bonding paste. The non-particulate solid components are made of high heat-conducting materials and dispersedly disposed on interfaces between heat sources and heat sinks. The liquid bonding paste is applied on interfaces between heat sources and heat sinks and filled into gaps formed among each of said non-particulate solid components so that the heat sources, heat sinks and each of said non-particulate solid components are bonded together.

### BACKGROUND OF THE INVENTION

1. Field of the Invention

The present invention relates to the connecting means between heat sources and heat sinks, in particular, a highly thermally conductive interface means for connecting heat sources with heat sinks to enhance the thermal conductivity therebetween.

2. Description of the Related Art

It is well known that adhesive bonding is one of the conventional methods used to connect a heat source with a heat sink, e.g., connecting a semiconductor die with a package substrate. In adhesive bonding, adhesive pastes are applied on the interface between the heat source and the heat sink for bonding them together.

To enhance heat transfer from the heat source to the heat sink, U.S. Pat. No. 6,515,061 disclosed a paste comprising a liquid carrier and thermally conductive filler particles. Said thermally conductive filler particles should theoretically enhance the thermal conductivity of said paste as compared to prior art pastes. However, in reality, said paste's thermal performance is questionable since the thermally conductive filler particles are dispersed in the liquid carrier in such a way that the heat transferring paths between any two filler particles are disrupted by the liquid carrier. The thermal conductivity thereof is hindered as a result.

### SUMMARY OF THE INVENTION

It is therefore an object of the present invention to provide an interface means having high thermal conductivity that can be used to connect heat sources and heat sinks to increase the heat transfer rate therebetween. It is another object of the present invention to provide a highly thermally conductive interface means to be used in microelectronic systems.

The aforementioned objects are achieved by a highly thermally conductive interface means in accordance with the present invention, which comprises a plurality of non-particulate solid components and a liquid bonding paste. The non-particulate solid components are made of high heat-conducting materials and dispersedly disposed on interfaces between heat sources and heat sinks. The liquid bonding paste is applied on interfaces between heat sources and heat sinks and filled into the gaps formed among the non-particulate solid components so that the heat sources, heat sinks and each of the non-particulate solid components are bonded together.

In one embodiment, the non-particulate solid component comprises a micro-pipe. Each of the micro-pipes is respectively dispersedly disposed on interfaces between heat sources and heat sinks. When used in microelectronic systems, the diameter of the micro-pipe is between 20 μm˜50 μm.

In another embodiment, the non-particulate solid component comprises a micro-stud. The interfaces between heat sources and heat sinks are populated by a plurality of the micro-studs. When used in microelectronic systems, the diameter of the upper surface of a micro-stud is between 20 μm˜50 μm.

### BRIEF DESCRIPTION OF THE DRAWINGS

These and other objects and features of the present invention will become clearer from the following description of the preferred embodiment given with reference to the attached drawings, wherein:

FIG. 1 is a perspective view of a first embodiment of a highly thermally conductive interface means in accordance with the present invention, which is used to bond a die to a substrate;

FIG. 2 is an exploded perspective view of the first embodiment of a highly thermally conductive interface means in accordance with the present invention, which is used to bond a die to a substrate;

FIG. 3 is a sectional view of the system shown in FIG. 1 taken along line 3--3;

FIG. 4 is an exploded perspective view of a second embodiment of a highly thermally conductive interface means in accordance with the present invention, which is used to bond a die to a substrate; and

FIG. 5 is a sectional view of the second embodiment shown in FIG. 4.

### DETAILED DESCRIPTION OF SPECIFIC EMBODIMENTS

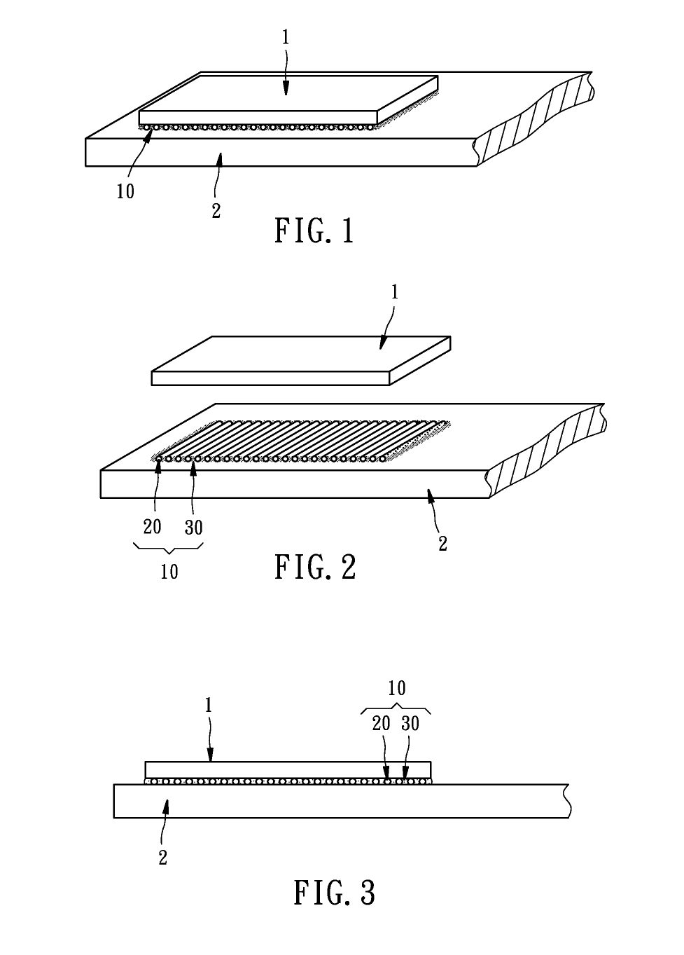

Referring firstly to FIGS. 1, 2 and 3, a highly thermally conductive interface means in accordance with the present invention is illustrated and designated generally by Reference Number 10. It is used to bond a semiconductor die 1 to a substrate 2.

Highly thermally conductive interface means 10 includes a plurality of micro-pipes 20 and a liquid bonding paste 30. Each of micro-pipes 20 is made of materials having high thermal conductivity, such as metals. To be used to bond a semiconductor die 1 to a substrate 2, each of micro-pipes 20 has a diameter between 20 μm˜50 μm.

Liquid bonding paste 30 can be a typical thermally conductive paste comprising acrylic thermoplastic resins, epoxy thermo-set resins or silicone resins.

In the bonding process, highly thermally conductive interface means 10 is constructed in such a way that each of micro-pipes 20 is firstly dispersedly disposed on the top surface of substrate 2; liquid bonding paste 30 is then applied on the top surface of substrate 2 and filled into the gaps formed among micro-pipes 20. Lastly, semiconductor die 1 is attached, using methods known in the art, to highly thermally conductive interface means 10 constructed on the top surface of substrate 2.

As disclosed above, heat generated from die 1 is conducted not only through bonding paste 30 but also directly through each of micro-pipes 20 so that heat dissipation of the system is effectively enhanced.

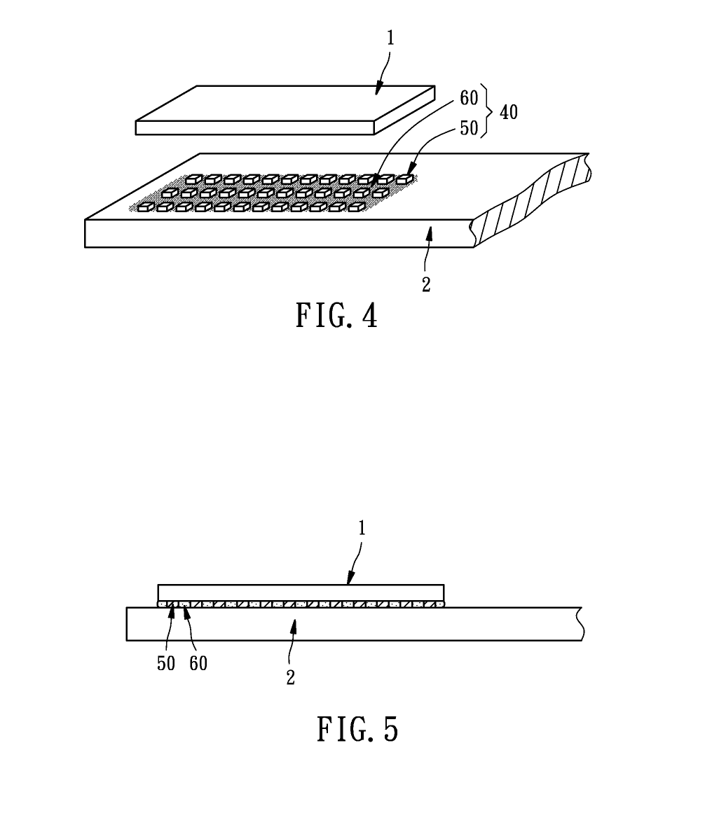

FIGS. 4 and 5 show a thermally conductive interface means 40 as provided in a second embodiment in accordance with the present invention. In this embodiment, thermally conductive interface means 40 includes a plurality of micro-studs 50 and liquid bonding paste 60. Micro-stud 50 is also made of materials having high thermal conductivity. To be used to bond a semiconductor die 1 to a substrate 2, each of micro-studs 50 also has a diameter between 20 μm˜50 μm. When thermally conductive interface means 40 is constructed between die 1 and substrate 2, heat generated from die 1 is conducted not only through bonding paste 60 but also directly through each of micro-studs 50 so that heat dissipation of the system is effectively enhanced.

What is claimed is:

1. An interface means for providing a highly thermally conductive connection between heat sources and heat sinks, said means comprising:
a plurality of non-particulate solid components made of high heat-conducting materials which are dispersedly disposed on interfaces between heat sources and heat sinks;
a liquid bonding paste applied on interfaces between heat sources and heat sinks and filled into gaps formed among each of said non-particulate solid components so that the heat sources, heat sinks and each of said non-particulate solid components are bonded together.

2. The means of claim 1, wherein said non-particulate solid component comprises a micro-pipe.

3. The means of claim 2, wherein the diameter of said micro-pipe is between 20 μm˜50 μm.

4. The means of claim 1, wherein said non-particulate solid component comprises a micro-stud.

5. The means of claim 4, wherein the diameter of said micro-stud is between 20 μm˜50 μm.

6. The means of claim 1, wherein said non-particulate solid component is made of metal materials.
An interface means for thermally coupling a heat dissipation device with a microelectronic device, said means comprising:
a plurality of non-particulate solid components made of high heat-conducting materials that are dispersedly disposed between the heat dissipation device and the microelectronic device;
a liquid bonding paste applied on interfaces between the heat dissipation device and the microelectronic device and filled into gaps formed among said non-particulate solid components so that the heat sources, heat sinks and each of said non-particulate solid components are bonded together.
